(19) United States
(12) Patent Application Publication
(10) Pub. No.: US 2023/0178397 A1
(43) Pub. Date: Jun. 8, 2023

(54) WAFER CLEANING WITH WAFER ASSEMBLY PRESENCE DETECTION

(71) Applicant: Skyworks Solutions, Inc., Irvine, CA (US)

(72) Inventors: Aristeo Realica Lanon, Mexicali (MX); Armando Valadez Anguiano, Mexicali (MX); Julian Sanchez Melchor, Mexicali (MX)

(21) Appl. No.: 18/075,223

(22) Filed: Dec. 5, 2022

Related U.S. Application Data
(60) Provisional application No. 63/286,238, filed on Dec. 6, 2021.

(51) Int. Cl. H01L 21/67; H01L 21/683; B08B 13/00; B08B 3/02; G01L 5/16

(52) U.S. Cl. CPC H01L 21/67253; H01L 21/6838; B08B 13/00; B08B 3/022; G01L 5/16; H01L 21/02068

(57) ABSTRACT

A system for cleaning a wafer has a vacuum source, a chuck table configured to support a wafer assembly and to be in communication with both the vacuum source and the wafer assembly, such that in use a suction force is applied to the wafer assembly via the chuck table. The system also includes a sensor component configured to detect the presence of the wafer assembly on the chuck table.

### CROSS-REFERENCE TO RELATED APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the disclosure relate to the field of semiconductor wafer processing technology, and more particularly, to systems and methods for cleaning a wafer.

### Description of the Related Technology

In certain wafer processing operations, such as cleaning a diced wafer, a wafer can be mounted on a chuck table. A chuck table is a disk shaped support configured to hold the wafer during the cleaning process.

The chuck table can form part of a wider cleaning tool, the cleaning tool being configured to clean the diced wafer by spraying a solvent across a surface of the wafer. The chuck table can be motor driven to facilitate this cleaning process.

### SUMMARY

According to one embodiment there is provided, a chuck table for supporting a wafer assembly during a cleaning process, the chuck table comprising: an axis of rotation; a first surface including an opening, the opening configured to be in communication with a vacuum source; and a second surface opposing the first surface, the second surface including a suction opening displaced radially from both the opening in the first surface and the axis, the suction opening being in communication with the opening in the first surface such that in use a suction force can be applied via the suction opening.

In one example the second surface may include a plurality of suction openings.

In one example the plurality of suction openings may be evenly distributed around a periphery of the second surface.

In one example a pair of opposing suction openings may be separated by a distance of 180 mm.

In one example each of the plurality of suction openings may be in communication with the opening in the first surface

In one example the chuck table may further comprise a cavity.

In one example the opening in the first surface and the suction opening in the second surface may be connected by means of the cavity.

In one example the chuck table may further comprise a plurality of holes configured to receive couplings suitable for securing the chuck table to a cleaning tool.

In one example the suction opening may extend 5 mm into the chuck table from the second surface.

In one example the chuck table may be disk shaped

In one example the suction opening may be positioned 2 mm away from the circumferential edge of the chuck table.

In one example the second surface may be formed from a single material such that it is unitary.

In one example the second surface may be formed from engineering plastics.

According to another embodiment there is provided, a chuck table for supporting a wafer assembly during a cleaning process, the chuck table comprising: an axis of rotation; a first surface including an opening, the opening configured to be in communication with a vacuum source; a second surface opposing the first surface, the second surface configured to support a wafer assembly, the wafer assembly including a wafer disposed on a portion of tape, the portion of tape having a first diameter that is larger than a second diameter of the wafer, and the wafer assembly being configured such that on a first face of the wafer assembly a peripheral area of the tape is uncovered by the wafer; and a suction opening in the second surface, the suction opening being displaced radially from both the opening in the first surface and the axis, and the suction opening being in communication with the opening in the first surface such that in use a suction force can be applied to the wafer assembly via the suction opening.

In one example the wafer of the wafer assembly may be diced.

In one example the wafer of the wafer assembly may be expanded.

In one example the wafer assembly may include a ring disposed around a periphery of the tape.

In one example the wafer may be expanded to a diameter of 160 mm.

In one example the wafer may be expanded to a diameter of 170 mm.

In one example the second surface may include a raised central portion.

In one example the raised central portion may be surrounded by a sunken peripheral portion.

In one example a geometry of the sunken peripheral portion may be complementary to a geometry of the ring of the wafer assembly.

In one example the chuck table may further comprise at least one indentation in a periphery of the chuck table, the indentation being configured to facilitate removal of the wafer assembly from the chuck table.

In one example the indentation may extend only through the sunken peripheral portion of the second surface.

In one example the suction opening may be configured to apply the suction force on a portion of a second face of the wafer assembly that directly opposes a portion of the peripheral area of the first face that is uncovered by the wafer.

According to another embodiment there is provided, a system for cleaning a wafer, the system comprising: a vacuum source; a chuck table configured to support a wafer assembly and to be in communication with both the vacuum source and the wafer assembly, such that in use a suction force is applied to the wafer assembly via the chuck table; and a sensor component configured to detect the presence of the wafer assembly on the chuck table.

In one example the sensor component may include a pressure sensor.

In one example the pressure sensor may be configured to monitor the pressure associated with the suction force on the wafer assembly.

In one example the pressure sensor may convert the measured pressure associated with the suction force on the wafer assembly into an electrical signal.

In one example the sensor component may further include a control component.

In one example the control component may be configured to determine whether the electrical signal from the pressure sensor is below a threshold value.

In one example the threshold value may correspond to a minimum signal that corresponds to the wafer assembly being correctly disposed on the chuck table.

In one example the control component may be configured to issue an appropriate command to interrupt a cleaning cycle if it is determined that the electrical signal is below the threshold value.

In one example the control component may be configured to issue an appropriate command to initiate a cleaning cycle if it is determined that the electrical signal is not below the threshold value.

In one example the control component may be configured to issue an appropriate command to continue a cleaning cycle if it is determined that the electrical signal is not below the threshold value.

In one example the wafer assembly may comprise a wafer disposed on a portion of tape, the portion of tape having a first diameter that is larger than a second diameter of the wafer, and the wafer assembly being configured such that on a first face of the wafer assembly a peripheral area of the tape is uncovered by the wafer.

In one example the pressure sensor may be configured to monitor the pressure associated with the suction force on a portion of a second face of the wafer assembly that directly opposes a portion of the peripheral area of the first face that is uncovered by the wafer.

According to another embodiment there is provided, a method for cleaning a wafer, the method comprising: disposing a wafer assembly on a chuck table of a cleaning tool; initiating a cleaning cycle; applying a suction force to the wafer assembly via the chuck table; and the cleaning tool monitoring the presence of the wafer assembly on the chuck table during the cleaning cycle.

In one example the presence of the wafer assembly on the chuck table may be monitored by means of a sensor component of the cleaning tool.

In one example the sensor component may include a pressure sensor.

In one example the pressure sensor may monitor the pressure associated with the suction force on the wafer assembly.

In one example the pressure sensor may convert the measured pressure associated with the suction force on the wafer assembly into an electrical signal.

In one example the sensor component may further include a control component.

In one example the control component may determine whether the electrical signal from the pressure sensor is below a threshold value.

In one example the threshold value may correspond to a minimum signal that corresponds to the wafer assembly being correctly disposed on the chuck table.

In one example initiating the cleaning cycle may trigger the control component to determine whether the electrical signal from the pressure sensor is below the threshold value.

In one example the control component may issue an appropriate command to prevent the cleaning cycle from starting if it is determined that the electrical signal is below the threshold value.

In one example the control component may issue an appropriate command to initiate the cleaning signal if it is determined that the electrical signal is not below the threshold value.

In one example the control component may periodically determine whether the signal is below the threshold value throughout the cleaning cycle.

In one example the control component may issue an appropriate command to interrupt the cleaning cycle if it is determined that the electrical signal is below the threshold value.

In one example the suction force may be applied to the wafer assembly by means of a vacuum source of the cleaning tool.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the inventions described herein. In the figures, each identical or nearly identical component that is illustrated in various figures is represented by a like numeral. For purposes of clarity, not every component may be labeled in every figure. In the figures:

FIG. 1 is an known example sequence of wafer processing for forming through-wafer features such as vias;

FIGS. 2A to 2Y show examples of structures at various stages of the processing sequence of FIG. 1;

FIG. 3A is an example known cleaning tool in its open configuration;

FIG. 3B is the example known cleaning tool of FIG. 3A in its closed configuration;

FIG. 4 is an example known chuck table configured for use with the known cleaning tool of FIGS. 3A and 3B;

FIG. 5 is an example chuck table configured for use with the known cleaning tool of FIGS. 3A and 3B according to aspects of the present disclosure;

FIG. 6 is a flowchart outlining the decision making process employed by the control component of the cleaning tool of FIGS. 3A and 3B according to aspects of the present disclosure;

FIG. 7 is an example chuck table configured for use with the known cleaning tool of FIGS. 3A and 3B according to aspects of the present disclosure;

FIG. 8 is a schematic diagram showing the internal structure of the chuck table of FIG. 7; and

FIG. 9 shows both the chuck table of FIGS. 5 and the chuck table of FIGS. 7 and 8 side-by-side.

### DETAILED DESCRIPTION

Aspects and embodiments described herein are directed to a chuck table for a wafer cleaning tool for having improved vacuum functionality.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

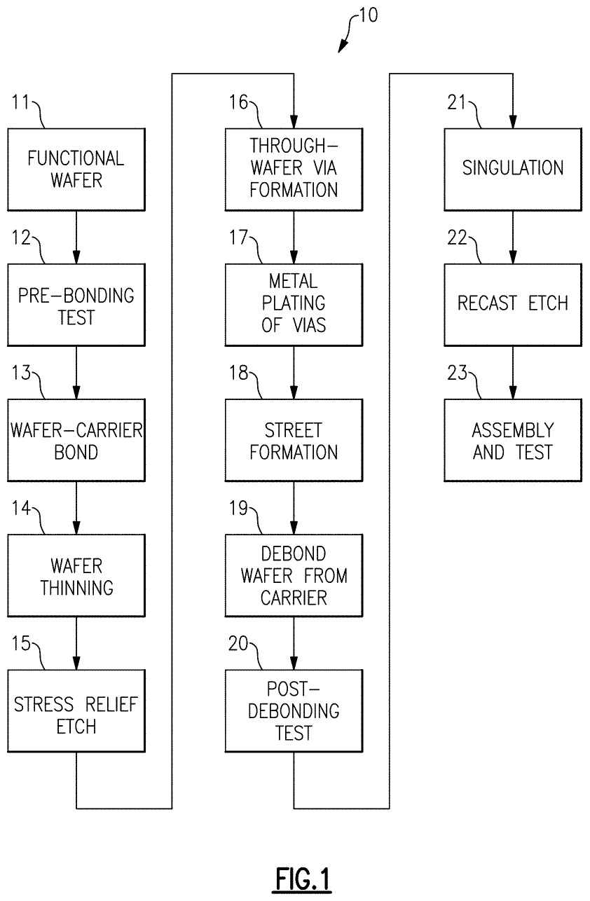

FIG. 1 shows an example of a process 10 where a functional wafer is further processed to form through wafer-features such as vias and back-side metal layers. As further shown in FIG. 1, the example process 10 can include bonding of a wafer to a carrier for support and/or to facilitate handling during the various steps of the process, and debonding of the wafer from the carrier upon completion of such steps. FIG. 1 further shows that such a wafer separated from the carrier can be further processed so as to yield a number of dies.

In the description herein, various examples are described in the context of GaAs substrate wafers. It will be understood, however, that some or all of the features of the present disclosure can be implemented in processing of other types of semiconductor wafers. Further, some of the features can also be applied to situations involving non-semiconductor wafers.

In the description herein, various examples are described in the context of back-side processing of wafers. It will be understood, however, that some or all of the features of the present disclosure can be implemented in front-side processing of wafers.

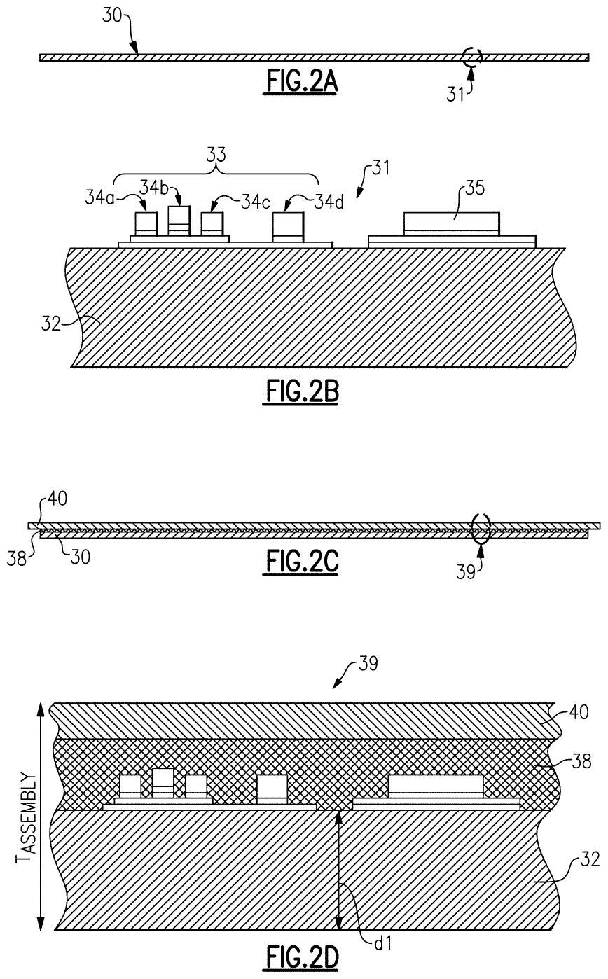

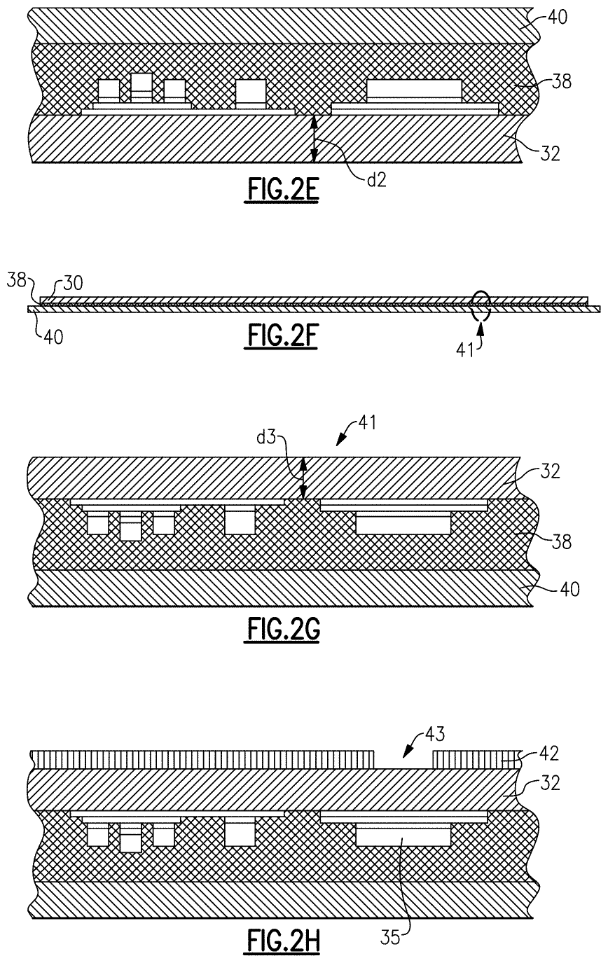

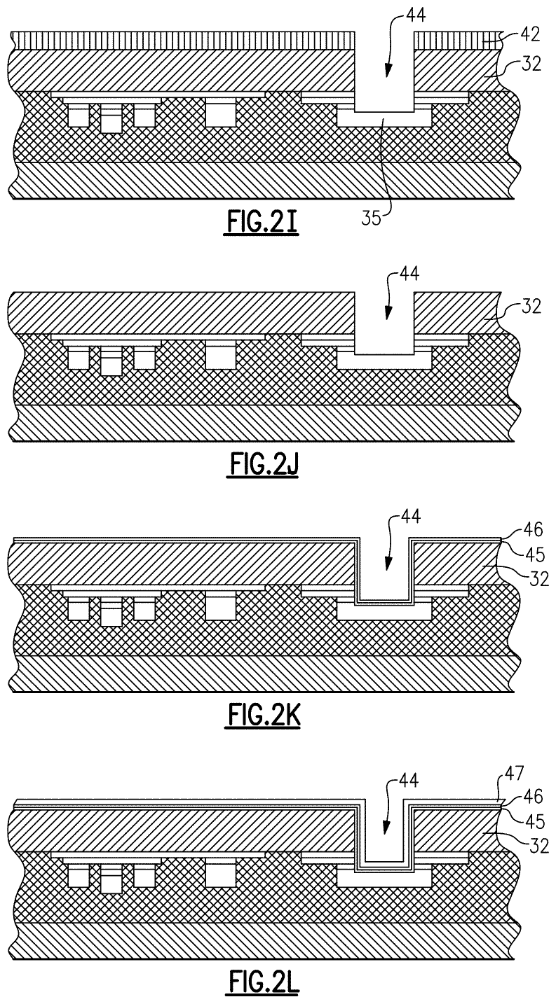

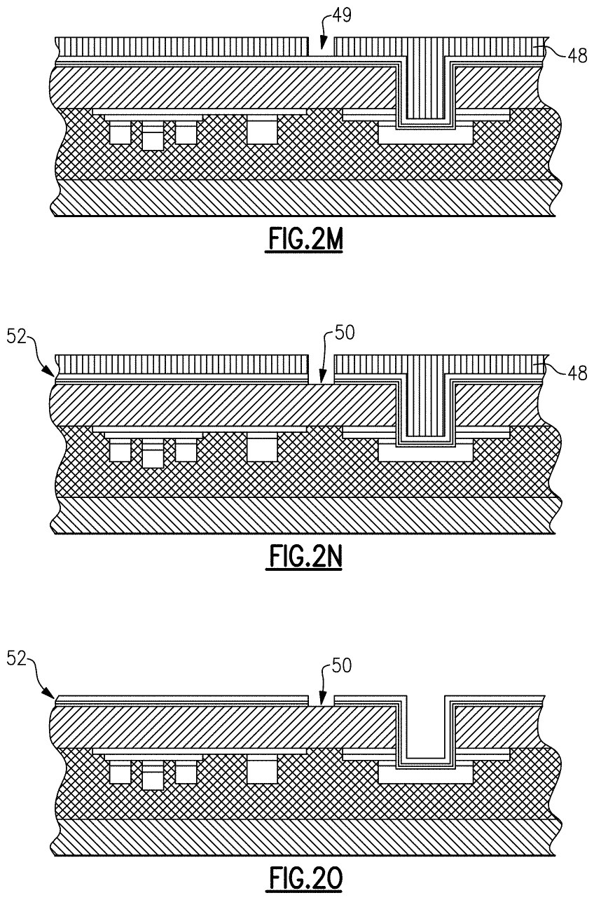

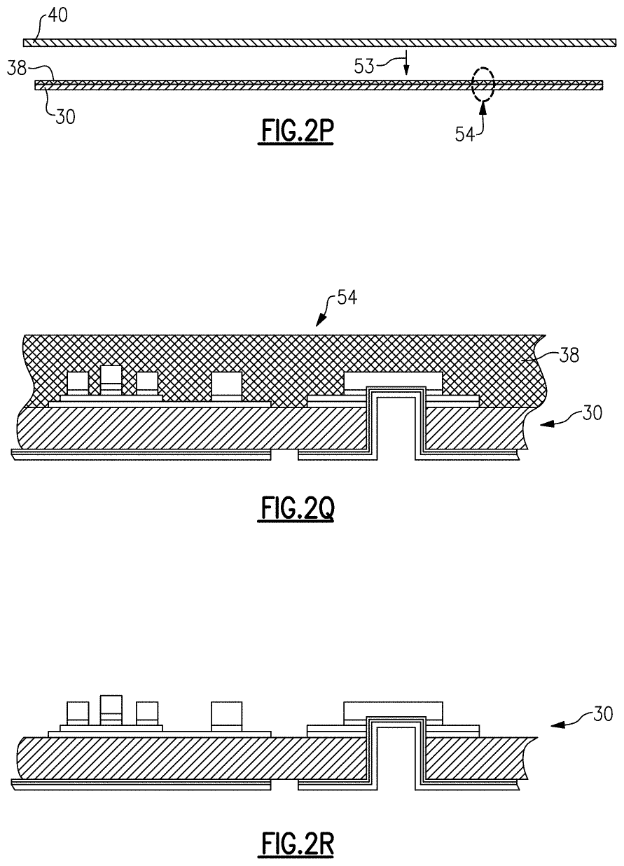

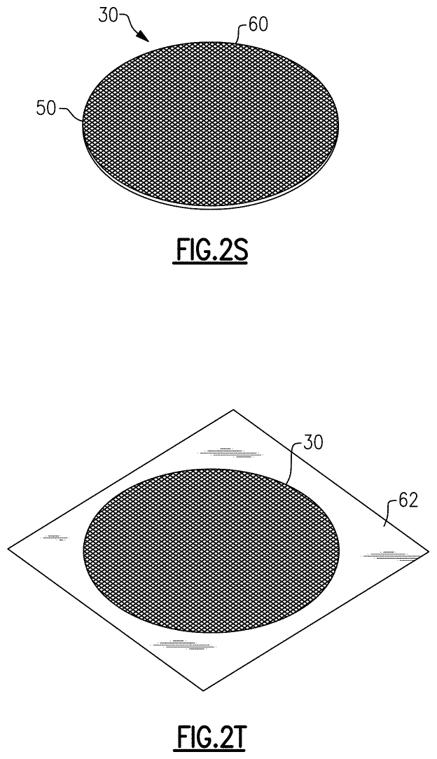

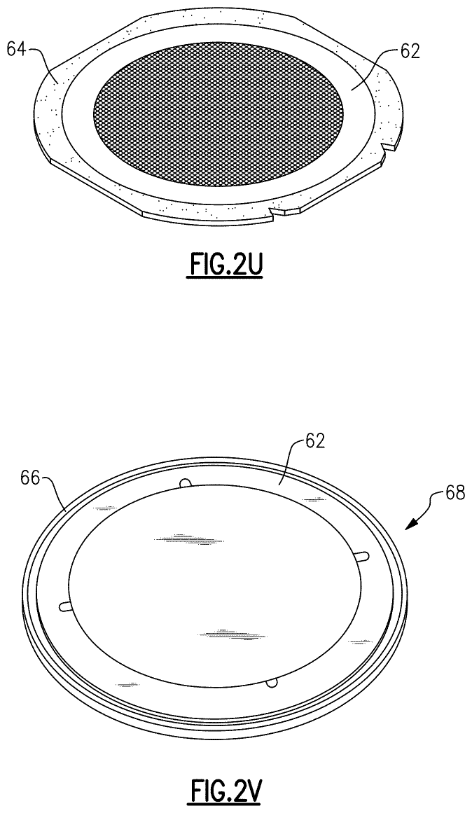

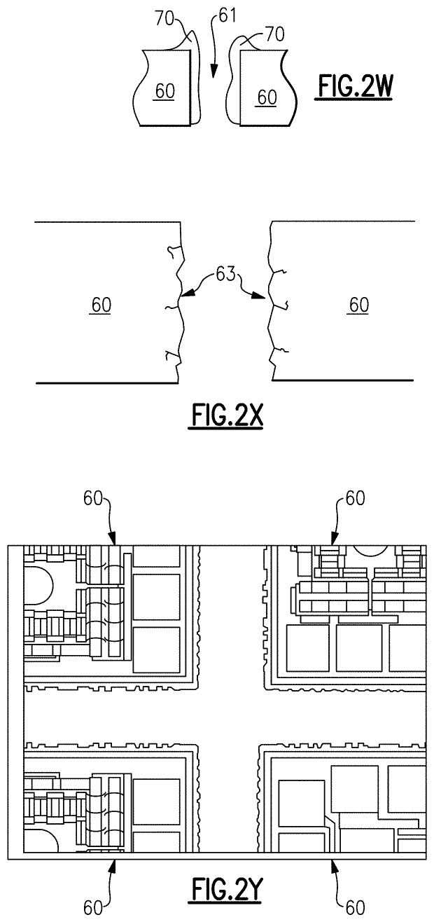

In the process 10 of FIG. 1, a functional wafer can be provided (block 11). FIG. 2A depicts a side view of such a wafer 30 having first and second sides. The first side can be a front side and the second side a back side.

FIG. 2B depicts an enlarged view of a portion 31 of the wafer 30. The wafer 30 can include a substrate layer 32 (e.g. a GaAs substrate layer). The wafer 30 can further include a number of features formed on or in its front side. In the example shown, a transistor 33 and a metal pad 35 are depicted as being formed on the front side. The example transistor 33 is depicted as having an emitter 34b, bases 34a, 34c, and a collector 34d. Although not shown, the circuitry can also include formed passive components such as inductors, capacitors, and source, gate and drain for incorporation of planar field effect transistors (FETs) with heterojunction bipolar transistors (HBTs). Such structures can be formed by various processes performed on epitaxial layers that have been deposited on the substrate layer.

Referring to the process 10 of FIG. 1, the functional wafer of block 11 can be tested (block 12) in a number of ways prior to bonding. Such a pre-bonding test can include, for example, DC and RF tests associated with process control parameters.

Upon such testing, the wafer can be bonded to a carrier (block 13). In certain implementations, such a bonding can be achieved with the carrier above the wafer. Thus, FIG. 2C shows an example assembly of the wafer 30 and a carrier 40 (above the wafer) that can result from the bonding step 13. In certain implementations, the wafer and carrier can be bonded using temporary mounting adhesives such as wax or commercially available Crystalbond™. In FIG. 2C, such an adhesive is depicted as an adhesive later 38.

An enlarged portion 39 of the bonded assembly in FIG. 2C is depicted in FIG. 2D. The bonded assembly can include the GaAs substrate layer 32 on which are a number of devices such as the transistor 33 and metal pad 35 as described in reference to FIG. 2B. The wafer 30 having such substrate 32 and devices (e.g., 33, 35) is depicted as being bonded to the carrier plate 40 via the adhesive layer 38.

As shown in FIG. 2D, the substrate layer 32 at this stage has a thickness of d1, and the carrier plate 40 has a generally fixed thickness. Thus, the overall thickness (Tassembly) of the bonded assembly can be determined by the amount of adhesive in the layer 38.

In a number of processing situations, it is preferable to provide sufficient amount of adhesive to cover the tallest feature(s) so as to yield a more uniform adhesion between the wafer and the carrier plate, and also so that such a tall feature does not directly engage the carrier plate. Thus, in the example shown in FIG. 2D, the emitter feature (34 b in FIG. 2B) is the tallest among the example features; and the adhesive layer 38 is sufficiently thick to cover such a feature and provide a relatively uninterrupted adhesion between the wafer 30 and the carrier plate 40.

Referring to the process 10 of FIG. 1, the wafer—now mounted to the carrier plate—can be thinned so as to yield a desired substrate thickness in blocks 14 and 15. In block 14, the back side of the substrate 32 can be ground away (e.g. via a two-step grind with coarse and fine diamond-embedded grinding wheels) so as to yield an intermediate thickness substrate (with thickness d2 as shown in FIG. 2E) with a relatively rough surface. In certain implementations, such a grinding process can be performed with the bottom surface of the substrate facing downward.

In block 15, the relatively rough surface can be removed so as to yield a smoother back surface for the substrate 32. In certain implementations, such removal of the rough substrate surface can be achieved by an O2 plasma ash process, followed by a wet etch process utilizing acid or base chemistry. Such an acid or base chemistry can include HCl, H2SO4, HNO3 H3PO4, H3COOH, NH4OH, H2O2, etc., mixed with H2O2 and/or H2O. Such an etching process can provide relief from possible stress on the wafer due to the rough ground surface.

In certain implementations, the foregoing plasma ash and wet etch process can be performed with the back side of the substrate 32 facing upward. Accordingly, the bonded assembly in FIG. 2F depicts the wafer 30 above the carrier plate 40. FIG. 2G shows the substrate layer with a thinned and smoothed surface, and a corresponding thickness of d3.

By way of an example, the pre-grinding thickness (d1 in FIG. 2D) of a 150 mm (also referred to as “6-inch”) GaAs substrate can be approximately 675 μm. The thickness d2 (FIG. 2E) resulting from the grinding process can be in a range of approximately 102 μm to 120 μm.The ash and etching processes can remove approximately 2 μm to 20 μm of the rough surface so as to yield a thickness of approximately 100 μm (d3 in FIG. 2G). Other thicknesses are possible.

In certain situations, a desired thickness of the back-side-surface-smoothed substrate layer can be an important design parameter. Accordingly, it is desirable to be able to monitor the thinning (block 14) and stress relief (block 15) processes. Since it can be difficult to measure the substrate layer while the wafer is bonded to the carrier plate and being worked on, the thickness of the bonded assembly can be measured so as to allow extrapolation of the substrate layer thickness. Such a measurement can be achieved by, for example, a gas (e.g., air) back pressure measurement system that allows detection of surfaces (e.g., back side of the substrate and the “front” surface of the carrier plate) without contact.

As described in reference to FIG. 2D, the thickness (Tassembly) of the bonded assembly can be measured; and the thicknesses of the carrier plate 40 and the un-thinned substrate 32 can have known values. Thus, subsequent thinning of the bonded assembly can be attributed to the thinning of the substrate 32; and the thickness of the substrate 32 can be estimated.

Referring to the process 10 of FIG. 1, the thinned and stress-relieved wafer can undergo a through-wafer via formation process (block 16). FIGS. 2H to 2J show different stages during the formation of a via 44. Such a via is described herein as being formed from the back side of the substrate 32 and extending through the substrate 32 so as to end at the example metal pad 35. It will be understood that one or more features described herein can also be implemented for other deep features that may not necessarily extend all the way through the substrate. Moreover, other features (whether or not they extend through the wafer) can be formed for purposes other than providing a pathway to a metal feature on the front side.

To form an etch resist layer 42 that defines an etching opening 43 (FIG. 2H), photolithography can be utilized. Coating of a resist material on the back surface of the substrate, exposure of a mask pattern, and developing of the exposed resist coat can be achieved in known manners. In the example configuration of FIG. 2H, the resist layer 42 can have a thickness in the range of about 15 μm to 20 μm.

To form a through-wafer via 44 (FIG. 21) from the back surface of the substrate to the metal pad 35, techniques such as dry inductively coupled plasma (ICP) etching (with chemistry such as BCl3/Cl2) can be utilized. In various implementations, a desired shaped via can be an important design parameter for facilitating proper metal coverage therein subsequent processes.

FIG. 2J shows the formed via 44, with the resist layer 42 removed. To remove the resist layer, photoresist strip solvents such as NMP (N-methyl-2-pyrrolidone) and EKC can be applied using, for example, a batch spray tool. In various implementations, proper removal of the resist material 42 from the substrate surface can be an important consideration for subsequent metal adhesion. To remove residue of the resist material that may remain after the solvent strip process, a plasma ash (e.g. O2) process can be applied to the back side of the wafer.

Referring to the process 10 of FIG. 1, a metal layer can be formed on the back surface of the substrate 32 in block 17. FIGS. 2K and 2L show examples of adhesion/seed layers and a thicker metal layer.

FIG. 2K shows that in certain implementations, an adhesion layer 45 such as a nickel vanadium (NiV) layer can be formed on surfaces of the substrate's back side and the via 44 by, for example, sputtering. Preferably, the surfaces are cleaned (e.g. with HCl) prior to the application of NiV. FIG. 2K also shows that a seed layer 46 such as a thin gold layer can be formed on the adhesion layer 45 by, for example, sputtering. Such a seed layer facilitates formation of a thick metal layer 47 such as a thick gold layer shown in FIG. 2L. In certain implementations, the thick gold layer can be formed by a plating technique.

In certain implementations, the gold plating process can be performed after a pre-plating cleaning process (e.g. O2 plasma ash and HCl cleaning). The plating can be performed to form a gold layer of about 3 μm to 6 μm to facilitate the foregoing electrical connectivity and heat transfer functionalities. The plated surface can undergo a post-plating cleaning process (e.g. O2 plasma ash).

The metal layer formed in the foregoing manner forms a back side metal plane that is electrically connected to the metal pad 35 on the front side. Such a connection can provide a robust electrical reference (e.g. ground potential) for the metal pad 35. Such a connection can also provide an efficient pathway for conduction of heat between the back side metal plane and the metal pad 35.

Thus, one can see that the integrity of the metal layer in the via 44 and how it is connected to the metal pad 35 and the back side metal plane can be important factors for the performance of various devices on the wafer. Accordingly, it is desirable to have the metal layer formation be implemented in an effective manner. More particularly, it is desirable to provide an effective metal layer formation in features such as vias that may be less accessible.

Referring to the process 10 of FIG. 1, the wafer having a metal layer formed on its back side can undergo a street formation process (block 18). FIGS. 2M to 2O show different stages during the formation of a street 50. Such a street is described herein as being formed from the back side of the wafer and extending through the metal layer 52 to facilitate subsequent singulation of dies. It will be understood that one or more features described herein can also be implemented for other street-like features on or near the back surface of the wafer. Moreover, other street-like features can be formed for purposes other than to facilitate the singulation process.

To form an etch resist layer 48 that defines an etching opening 49 (FIG. 2M), photolithography can be utilized. Coating of a resist material on the back surface of the substrate, exposure of a mask pattern, and developing of the exposed resist coat can be achieved in known manners.

To form a street 50 (FIG. 2N) through the metal layer 52, techniques such as wet etching (with chemistry such as potassium iodide) can be utilized. A pre-etching cleaning process (e.g. O2 plasma ash) can be performed prior to the etching process. In various implementations, the thickness of the resist 48 and how such a resist is applied to the back side of the wafer can be important considerations to prevent certain undesirable effects, such as via rings and undesired etching of via rim during the etch process.

FIG. 20 shows the formed street 50, with the resist layer 48 removed. To remove the resist layer 48, photoresist strip solvents such as NMP (N-methyl-2-pyrrolidone) can be applied using, for example, a batch spray tool. To remove residue of the resist material that may remain after the solvent strip process, a plasma ash (e.g. O2) process can be applied to the back side of the wafer.

In the example back-side wafer process described in reference to FIGS. 1 and 2, the street 50 formation and removal of the resist 48 yields a wafer that no longer needs to be mounted to a carrier plate. Thus, referring to the process 10 of FIG. 1, the wafer is debonded or separated from the carrier plate in block 19. FIGS. 2P to 2R show different stages of the separation and cleaning of the wafer 30.

In certain implementations, separation of the wafer 30 from the carrier plate 40 can be performed with the wafer 30 below the carrier plate 40 (FIG. 2P). To separate the wafer 30 from the carrier plate 40, the adhesive layer 38 can be heated to reduce the bonding property of the adhesive. For the example Crystalbond™ adhesive, an elevated temperature to a range of about 130° C. to 170° C. can melt the adhesive to facilitate an easier separation of the wafer 30 from the carrier plate 40. Some form of mechanical force can be applied to the wafer 30, the carrier plate 40, or some combination thereof, to achieve such separation (arrow 53 in FIG. 2P). In various implementations, achieving such a separation of the wafer with reduced likelihood of scratches and cracks on the wafer can be an important process parameter for facilitating a high yield of good dies.

In FIGS. 2P and 2Q, the adhesive layer 38 is depicted as remaining with the wafer 30 instead of the carrier plate 40. It will be understood that some adhesive may remain with the carrier plate 40.

FIG. 2R shows the adhesive 38 removed from the front side of the wafer 30. The adhesive can be removed by a cleaning solution (e.g. acetone), and remaining residues can be further removed by, for example, a plasma ash (e.g. O2 process).

Referring to the process 10 of FIG. 1, the debonded wafer of block 19 can be tested (block 20) in a number of ways prior to singulation. Such a post-debonding test can include, for example, resistance of the metal interconnect formed on the through-wafer via using process control parameters on the front side of the wafer. Other tests can address quality control associated with various processes, such as quality of the through-wafer via etch, seed layer deposition, and gold-plating.

FIG. 2S illustrates a GaAs wafer 30 with a plurality of individual integrated circuits 60 (also referred to herein as dies). As shown in FIG. 2S, streets 50 have been formed in the regions between each integrated circuit 60 on the wafer 30.

Following street formation, the wafer 30 is placed onto cutting tape 62, with the back side of the GaAs wafer 30 adhering to the cutting tape 62 in the manner shown in FIG. 2T. The cutting tape is further mounted to a dicing frame 64 to hold the wafer 30 during the cutting process, as shown in FIG. 2U. Next, the integrated circuit dies are singulated or diced by cutting through the GaAS wafer 30 along the pre-formed streets 50. A scribe may be applied to the streets in order to mechanically singulate the integrated circuit dies. Alternatively, a laser may be used to burn through the streets 50. Mechanical scribing is inexpensive, but is typically less accurate than laser singulation, and may cause damage to the die. Laser singulation is more accurate and reduces damage, but at increased expense.

Referring to FIG. 2V, once the integrated circuit dies have been singulated, the cutting tape 62 is stretched apart. This stretching ensures that the dies 60 have been singulated, as it results in widening the separation between each of the dies. The cutting tape may be stretched until the tape 62 is visible between each of the dies. FIG. 2V shows a wafer that has undergone the expansion process. During the stretching process, the wafer and tape are fitted to a grip ring 66 which retains the wafer 30 and tape 62 in their expanded state. The grip ring 66 is positioned between the periphery of the wafer 30 and the inner perimeter of the dicing frame 64. Once stretched, the dicing frame 64 and the excess tape 62 surrounding the grip ring 66 is removed. What remains is referred to as a wafer assembly 68 herein, comprising a wafer 30, cutting tape 62 and ring 66. The wafer assembly 68 has two opposing faces. The wafer side is defined as the side on which the wafer 30 is disposed. The remaining face on which the wafer 30 is not disposed is referred to herein as the tape side.

Referring still to FIG. 2V, the wafer side of the wafer assembly 68 comprises a generally disk-shaped wafer 30 disposed on cutting tape 62. The cutting tape 62 is also disk shaped, with a larger radial extent than the wafer 30. The wafer 30 is generally positioned in the center of the cutting tape 62, such that a peripheral ring-shaped area of the cutting tape 62 is uncovered by the wafer 30 on the wafer side of the wafer assembly 68. In other words, the wafer assembly 68 comprises a wafer 30 disposed on a portion of tape 62, the portion of tape 62 having a first diameter that is larger than a second diameter of the wafer 30, and the wafer assembly 68 being configured such that on a first face of the wafer assembly 68 a peripheral area of the tape 62 is uncovered by, not covered by, the wafer 30. The ring 66 is disposed around the periphery of the cutting tape 62 such that the ring 66 defines the thickest section of the wafer assembly 68.

In the context of laser cutting, FIG. 2W shows an effect on the edges of adjacent dies 60 cut by a laser. As the laser makes the cut, a rough edge feature 70 (commonly referred to as a recast) typically forms. Presence of such a recast can increase the likelihood of formation of a crack therein and propagating into the functional part of the corresponding die.

Thus, referring to the process in FIG. 1, a recast etch proves using acid and/or base chemistry (e.g. similar to the examples described in reference to block 15) can be performed in block 22. Such etching of the recast feature and defects formed by the recast, increases the die strength and reduces the likelihood of die crack failures (FIG. 2X).

Referring to the process of FIG. 1, the recast etched dies (FIG. 2Y) can be further inspected and subsequently be packaged.

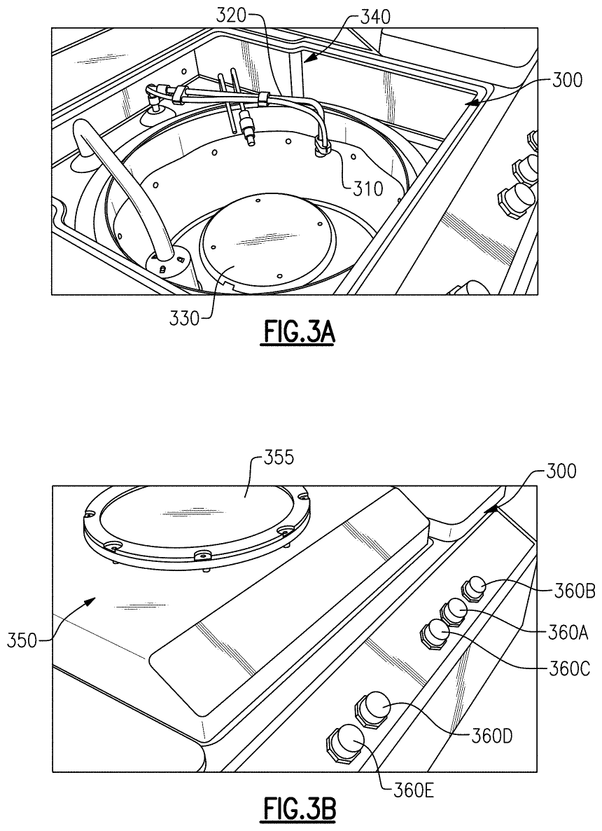

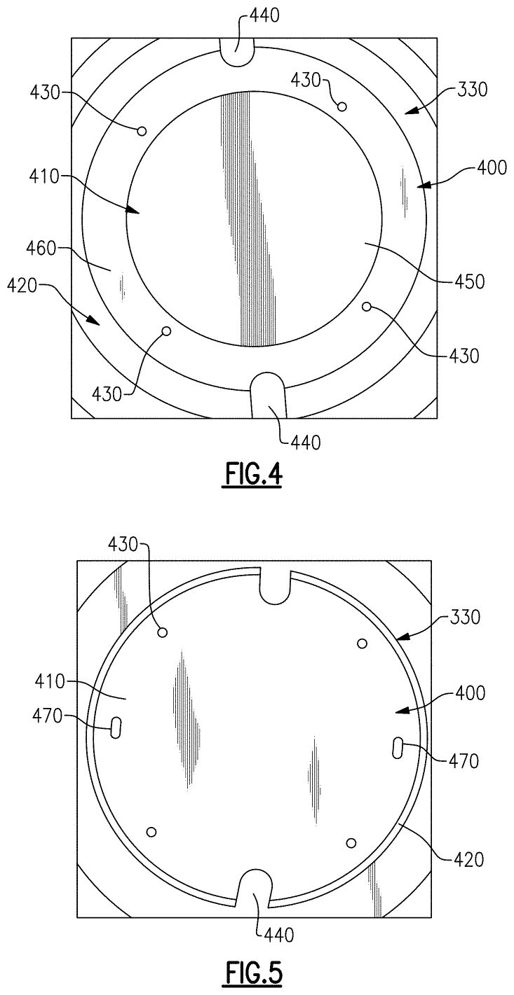

After singulation, remnants or debris from the cutting process may remain on the wafer. The wafer may therefore be cleaned after singulation to remove such residue. This cleaning process may be carried out while the wafer remains attached to the cutting tape and ring. FIGS. 3A and 3B show a known cleaning tool 300 (also referred to herein as a washer) configured to clean a wafer after singulation. The cleaning is achieved by cleaning fluid (e.g. an alcohol) sprayed through a spray head 310. The spray head 310 is on a swivel arm 320. The swivel arm 320 allows the solvent spray to sweep across the wafer.

In the example shown, a chuck table 330 is provided for holding the wafer assembly 206 during the foregoing cleaning process. A chuck table is a disk shaped support configured to hold the wafer during the cleaning process. Chuck tables are well known in the field of cleaning tools for semiconductor wafers. The chuck table 330 is rotated by a motor (not shown). When supporting a wafer assembly 206, the rotation of the chuck table 330 leads to rotation of the wafer assembly. The combination of the rotating chuck table 330 and swivel arm 320 allows the cleaning fluid to be applied to the entirety of the wafer.

The cleaning tool 300 further comprises an openable housing 340. Components (e.g. swivel arm 320 and chuck table 330) of the cleaning tool 300 are disposed within the housing 340. The housing 340 is dimensioned to capture fluids during the cleaning process and to contain fluids being spun away from the wafer assembly 206 as the chuck table-wafer assembly rotates. The housing is additionally configured to protect and contain the wafer during the cleaning process. The housing 340 further comprises a cover 350. The cover 350 is configured to allow a manual operator to open the housing 340 such that components (e.g. swivel arm 320 and chuck table 330) of the cleaning tool 300 are exposed. The cover 350 is also configured to allow a manual operator to close the housing 340 such that components (e.g. swivel arm 320 and chuck table 330) of the cleaning tool 300 are confined within the housing 340. The cover 350 further comprises a window 355. The window 355 allows the operator to observe the cleaning process even when the cleaning tool 300 is in its closed configuration. FIG. 3A shows the cleaning tool 300 in said open configuration and FIG. 3B shows the housing 340 in said closed configuration.

In the example shown, the chuck table 330 is positioned to receive a wafer assembly. With the housing 340 in its open configuration, an operator positions a wafer assembly 206 on the chuck table 330. The wafer assembly 206 is positioned such that the tape side of the wafer assembly 206 is in physical contact with the chuck table 330. The manual operator then closes the lid 350 of the housing 340 and initiates the cleaning process. The cleaning process is initiated in this example by pressing a button 360A. Pressing button 306A instructs the cleaning tool 300 to execute a cleaning cycle. The cleaning tool 300 further comprises a plurality of functional buttons 360 B-E which permit the operator to switch the washer 300 on/off and open/close the cleaning tool housing 340. Once the cleaning cycle is initiated, the wafer assembly is spun by the chuck table/motor. The chuck table/motor reaches speeds of around 2000 rpm at certain points of the cleaning process. The swivel arm 320 sweeps across the radial span of the wafer assembly with the spray head 310 positioned adjacent to the wafer side of the wafer assembly. In this way, cleaning fluid is sprayed onto a surface of the wafer. Once the cleaning cycle is complete, the manual operator opens the cover 350 of the housing 340. The wafer assembly can then be removed from the chuck table 330 by the operator.

Due to the high rotation speeds reached at some points during the cleaning cycle, there is a known problem of wafer assemblies being thrown off the chuck table 330 and subsequently damaged.

FIG. 4 shows a known chuck table 330 configured to be used with the known cleaning tool 300 in more detail. The chuck table 330 has a generally circular cross section (i.e. is generally disk shaped). Generally disk-shaped refers to the fact that the peripheral edge of the chuck table 330 includes features such as indentations (referred to in further detail below). Said features interrupt the perimeter of the chuck table 330. In this way, the chuck table 330 is not perfectly disk shaped. Such a circular cross section is complementary to the disk-shape of a wafer/wafer assembly. The chuck table 330 comprises a surface 400. The surface 400 is configured to support/hold a wafer during the cleaning process. The surface 400 comprises a central portion 410 and a peripheral portion 420. The central portion 410 is raised relative to the peripheral portion 420. The central portion 410 also has a generally circular cross section. The peripheral portion 420 surrounds the central portion 410. The peripheral portion 420 has a generally ring shaped cross section. The inner perimeter of the peripheral portion 420 is complementary to the shape of the outer perimeter of the central portion 410. In other words, the surface 400 comprises a central raised portion 410 surrounded by a sunken peripheral portion 420. As discussed above with reference to FIG. 2V, the ring 66 of the wafer assembly 68 defines the thickest portion of the wafer assembly. The sunken portion 420 is therefore configured to accommodate the extra thickness of the wafer assembly 68 at the location of the ring 66. In this way, when a wafer assembly 68 is disposed on the chuck table 330 such that the ring 66 rests on the sunken portion 420, lateral movement of the wafer assembly 68 is prevented. In other words, the geometry of the sunken peripheral portion 420 is complementary to a geometry of the ring 66 of the wafer assembly 68.

The chuck table 330 further comprises holes 430. In this example there are four holes 430. The holes 430 are disposed around a periphery of the central portion 410. The four holes 430 are evenly distributed around the periphery of the raised central portion 410. In other words, the positioning of the holes 430 corresponds to those of the vertices of a square. The purpose of these holes 430 is to facilitate mounting the chuck table 330 on the cleaning tool 300 such that the chuck table 330 can be driven by a motor (not shown) of the cleaning tool to rotate. These mounting holes 430 are therefore configured to receive couplings that are suitable for securing the chuck table 330 to the cleaning tool. Suitable couplings are screws, for example. There are four mounting holes 430 in the chuck table 330 in this example to complement the cleaning tool 300 of FIGS. 3A and 3B. However, it is to be understood that the means for mounting the chuck table 330 to the motor can differ in other examples/for other cleaning tools.

Still referring to FIG. 4, the chuck table 330 further comprises a pair of handling indentations or notches 440. These indentations 440 are located in the circumferential edge of the chuck table 330. The indentations 440 are positioned approximately opposite from one another. Each notch 440 is further positioned to be approximately equidistant from two neighboring mounting holes 430. The indentations 440 have a generally arch shaped periphery. The purpose of these handling notches 440 is to facilitate the removal a wafer assembly that is disposed on the chuck table 330. The indentations 440 are configured to be sufficiently deep such that when a wafer assembly is disposed on the chuck table, the wafer assembly will cover at least a portion of the indentations 440. As a result, a portion of the tape side of the wafer assembly will be uncovered by the chuck table 330. An operator can therefore use the exposed portion of the tape side of the wafer assembly to lift the wafer assembly from the chuck table 330.

The central portion 410 of the chuck table further comprises a central disk shaped section 450 and a ring shaped section 460. The ring shaped section 460 extends around the periphery of the central disk shaped section 450. The disk shaped section 450 and ring shaped section 460 are both made from differing materials. The disk shaped section 450 comprises a porous material. The ring shaped section 460 comprises engineering plastics. Both the mounting holes 430 and handling indentations 440 are located in the ring shaped section 460 of the chuck table.

The central porous section 450 of the chuck table 330 is configured to be in communication with a vacuum source (not shown) of the cleaning tool. As previously discussed, due to the high rotation speeds reached at some points during the cleaning cycle, there is a problem with wafer assemblies being thrown off the chuck table 330 and subsequently damaged. The central porous section 450 is, therefore, configured to deliver a suction force on the wafer assembly such as to hold the wafer assembly and reduce the likelihood of the wafer assembly being damaged and subsequently rejected.

The boundary between the porous section 450 of the chuck table and ring shaped section 460 of the chuck table leads to a step in the surface 400 of the chuck table configured to hold the wafer. This leads to an uneven surface. The uneven surface promotes die cracking when a suction force is applied to the wafer assembly. This problem is exacerbated by cleaning taking place post-singulation.

According to some aspects of the present disclosure, a chuck table with improved vacuum capability is provided.

FIG. 5 shows a chuck table 330 according to aspects of the present disclosure. The chuck table 330 is also configured for use with the cleaning tool shown in FIGS. 3A and 3B. The chuck table 330 of FIG. 5 shares a number of like features with the known chuck table 330 of FIG. 4, including a generally disk shape, four mounting holes 430, and a pair of handling indentations 440. Like features have been given like reference numerals. However, the chuck table 330 shown in FIG. 5 does not have a circular disk shaped section made of porous material. Instead, the surface 410 of the chuck table 330 comprises a single material and is unitary. There is, therefore, no longer a boundary between two materials that leads to an uneven surface that promotes die cracking, as discussed above. In the example shown, the single material is engineering plastics. Furthermore, the central portion 410 of the chuck table 330 radially extends further than that of the chuck table 330 shown in FIG. 4. Furthermore, the peripheral portion 420 is thinner than that of the chuck table 330 shown in FIG. 4. This change was made to adapt the dimensions of the chuck table 330 to the dimensions of wafer assemblies that will be likely be cleaned using the cleaning tool of FIGS. 3A and 3B.

Referring still to FIG. 5, the chuck table 330 further comprises a pair of suction openings 470 (also referred to herein as vacuum holes). These suction openings 470 are located in the surface 410 of the chuck table. The configuration of the suction openings 470 is significant. The vacuum holes 470 are located in the central portion 410 of the chuck table 330. The vacuum holes 470 are opposite from one another. The vacuum holes 470 are also positioned approximately 90 degrees along the circumferential edge of the chuck table 330 from each handling indentation. In this way, the suction openings 470 are evenly distributed around the periphery of the surface 410. In other words, the suction openings 470 are radially displaced from the center of rotation of the chuck table. The suction openings 470 are configured to be in communication with a vacuum source (not shown). The vacuum source forms part of the cleaning tool 300. The vacuum holes 470 are positioned such that they deliver a suction force on the tape side of a portion of the wafer assembly. As will be discussed in more detail below with reference to FIG. 8, the suction force is delivered to the tape side of the wafer assembly by means of a hole in the chuck table 330 that is configured to be in communication with the vacuum source of the cleaning tool, and a plurality of cavities designed to be in communication with both said hole and the suction openings 470. Although in this example there are two suction openings 470, it is to be understood that other configurations in which a plurality of suction openings are distributed evenly around a periphery of a chuck table are possible.

One function of the suction openings 470, like the porous section 450 of the known chuck table 330 shown in FIG. 4, is to hold of the wafer assembly during the cleaning process such as to avoid the above described problem of the wafer assembly being thrown off the chuck table 330 and damaged when high rotation speeds are reached during the cleaning process.

Referring now to FIGS. 3A, 3B and 5, the cleaning tool 300 includes a sensor component (not shown). The sensor component is configured to detect the presence of the wafer assembly on the chuck table 330. The sensor component is able to detect the presence of material by vacuum pressure. This vacuum check detects vacuum presence on the wafer assembly in real time via the suction openings 470 when a wafer assembly is disposed on the chuck table 330. In other words, the vacuum pressure on the chuck table 330 is monitored in real time. As explained above, for the cleaning process, the chuck table 330 and wafer assembly are mounted on a cleaning tool 300 and a manual operator then initiates the cleaning cycle, during which high rotational speeds of the chuck table/wafer assembly are reached. If the presence of the wafer assembly is not detected during the cleaning cycle, or when the manual operator attempts to initiate the cleaning cycle, the cleaning tool is configured to interrupt the cleaning cycle. This brings the rotation of the chuck table/wafer assembly to a stop. Reasons why the wafer assembly may not be detected include the wafer assembly not being positioned correctly on the chuck table 330, such that the wafer assembly is not being secured to the chuck table 330 via vacuum pressure. In this way, the vacuum functionality of the chuck table 330 facilitates both a detection mechanism and a mechanism for holding the wafer assembly on the chuck table 330 firmly.

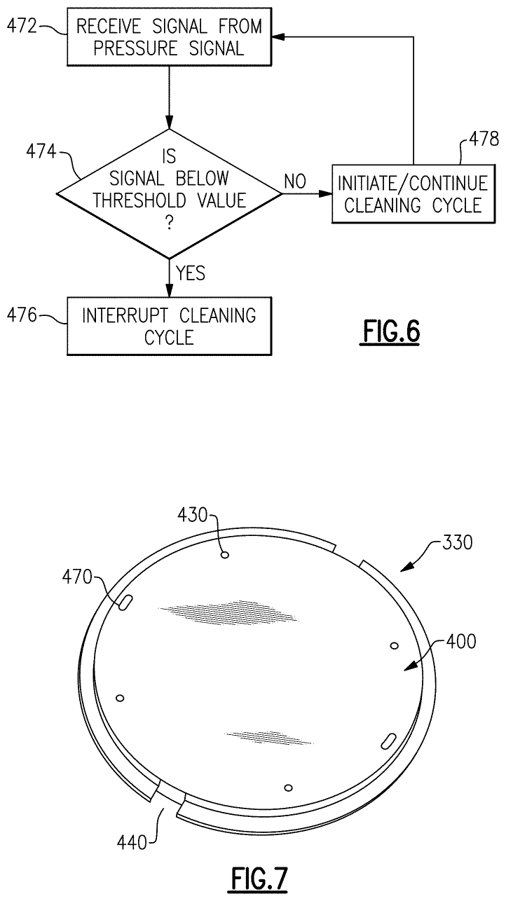

In some examples, the sensor component comprises a pressure sensor. The pressure sensor monitors the pressure associated with the suction being provided on the wafer assembly. The pressure sensor is a known pressure sensor that measures pressure by converting pressure into an analog electrical signal. In some examples the sensor component further comprises a control component. The control component is configured to determine whether the electrical signal from the pressure sensor falls below a threshold value. Said threshold value is chosen as the minimum signal that corresponds to the wafer assembly being properly seated on the chuck table. In other words, if the signal from the pressure sensor falls below said threshold value, the wafer assembly is not properly seated on the chuck table. The decision making process employed by the control component is summarized in the flowchart of FIG. 6. After receiving the signal from the pressure sensor (block 472), if the control component determines that the electrical signal has fallen below the threshold value (block 474), an appropriate command can be issued by the control component so as to interrupt the cleaning cycle (block 476). If the control component determines otherwise (block 474), an appropriate command can be issued by the control component so as to initiate the cleaning cycle/continue the cleaning cycle (block 478). The control component periodically determines whether the signal is below the threshold value throughout the cleaning cycle and issues an appropriate command to interrupt/continue the cleaning cycle if it is determined that the electrical signal is below/above the threshold value.

According to some aspects of the present disclosure, a chuck table is provided with improved vacuum capability/functionality. As discussed above with reference to FIG. 4, known chuck tables were configured to exert a suction force on wafer assemblies via a relatively large central porous section 450 that promoted die cracking due to the uneven surface caused by the boundary between the differing materials of the central porous section 450 and the peripheral section 460 of the chuck table 330. Furthermore, applying the suction force on a large area of the wafer assembly, which comprises a diced wafer, additionally promotes die cracking. Referring now to FIG. 5, the chuck table according to aspects of the present disclosure is configured to apply a suction force to a much smaller portion of the wafer assembly via suction openings 470. The surface 400 of the chuck table 330 further comprises a single material and is unitary. The surface 400 is, therefore, even. This reduces the likelihood of die cracking occurring due to the vacuum functionality of the chuck table 330. Furthermore, the chuck table 330 according to aspects of the present disclosure facilitates the tape detection discussed above. This allows the cleaning process to be interrupted if the wafer assembly is not positioned correctly on the chuck table. By stopping the rotation of the wafer assembly, the wafer being thrown off the chuck table and subsequently damaged and rejected is avoided.

According to some aspects of the present disclosure, a second embodiment of a chuck table with improved vacuum capability is provided.

The diameter of a typical wafer to be used with a chuck table according to aspects of the present disclosure is 6 inches or 150 mm. STD expanded wafers have a diameter of 160+/−3 mm. HCL expanded wafers have a diameter of 170+/−3 mm. Referring to the chuck table 330 of FIG. 5, for expanded wafers, the suction holes 470 tend to be positioned such that they deliver a suction force on a portion of the tape side of the wafer assembly which directly opposes the position of the edge of the wafer on the wafer side of the wafer assembly. In other words, a suction force is exerted on the edge of the diced wafer. The suction force is, therefore, prone to causing die cracking and damage, such as chipping, on the edges of the wafer. These damaged wafers are then rejected.

FIG. 7 shows a second embodiment of a chuck table according to aspects of the present disclosure. Embodiments of FIGS. 5 and 7 share similarities and like features have been given like reference numerals. The configuration of the suction openings 470 is significant and is discussed in more detail below.

As discussed above, the chuck table 330 is configured to support a wafer assembly such as that shown in FIG. 2V. The suction openings 470 are positioned in the chuck table 330 such that when a wafer is disposed on the chuck table 330, each suction opening 470 is in physical contact with a portion of the tape side of the wafer assembly of which on the wafer side the tape is uncovered by the wafer. In use, the suction openings 470 are configured to deliver a suction force on said portions of the wafer assembly. In other words, the vacuum pressure only has contact with the tape of the wafer assembly and not with the wafer itself. For typical wafer dimensions, the suction openings are separated by a distance of 180+/−1 mm and/or are positioned 2 mm away from the circumferential edge of the chuck table. The suction openings 470 further extend approximately 5 mm into the chuck table from the surface 400.

Referring now to FIG. 8, the chuck table 330 comprises a hole 480 or opening in a bottom surface 490 of the chuck table 330. Herein, the bottom surface 490 refers to a surface of the chuck table opposing the surface 400 on which a wafer assembly is placed. The hole 480 extends through a portion of the chuck table 330, in a direction towards the surface 400. However, the hole 480 does not span the entire thickness of the chuck table 330. The hole 480, therefore, does not create an opening in the surface 400. The hole 480 is positioned approximately at the center of the surface 480 of the chuck table. The suction openings 470 are radially displaced from the position of the hole 480. When mounted on the cleaning tool 300, the hole 480 is further in communication with a vacuum device (not shown). As a result, the hole 480 acts as a vacuum source for the chuck table 330.

Still referring to FIG. 8, the chuck table 330 further comprises a plurality of cavities (also alternatively referred to as passages, tunnels, or channels) 500. The cavities 500 radially extend from the vacuum source hole 480 to each of the suction openings 470. In the example shown, there are two cavities 500. Each cavity 500 corresponds to one of the two suction openings 470. The cavities are positioned within the chuck table 330, such that they do not extend through to either of surfaces 400 or 490. Both cavities 500 are in communication with the vacuum source hole 480. Each cavity 500 is further in communication with one of the suction openings 470. In this way, when mounted on the cleaning tool 300, suction formed at the vacuum source hole 480 is distributed along the cavities 500 to the suction openings 470. The result is a suction force being applied to a wafer assembly disposed on the surface 400 of the chuck table 330 via the suction openings 470.

As discussed with reference to FIGS. 5 and 6, the suction force on the wafer assembly serves two purposes. Firstly, it secures the wafer assembly to the chuck table. Secondly, it facilitates monitoring the presence of the wafer assembly on the chuck table. The same applies to the chuck table of FIGS. 7 and 8. However, the position of the suction openings 470 means that it is the presence of the tape of the wafer assembly that is specifically being monitored. In other words, the pressure sensor is configured to monitor the pressure associated with the suction force on a portion on a second face of the wafer assembly that directly opposes a portion of the peripheral area of the first face of the wafer assembly that is uncovered by the wafer.

Referring still to both FIGS. 7 and 8, the configuration of the handling indentations 440 is also significant. The radial extent of the handling indentations 440 is less than those of the chuck tables 330 shown in FIGS. 4 and 5. Furthermore, the indentations 440 do not have an arch-shaped perimeter like those of the chuck tables shown in FIGS. 4 and 5. Instead, the edge of the indentation 440 that defines how far the indentation 440 extends into the chuck table 330 follows the curvature of the edge of the central raised portion 410 of the chuck table 330. In other words, the indentation extends only through the sunken peripheral portion 420 of the surface 400. In this way, the indentation 440 spans a smaller area than those of the known chuck tables 330. As a result, when a wafer assembly is disposed on the chuck table 330, the handling indentations 440 will leave a smaller area of the tape side of the wafer-assembly exposed than known chuck tables 330. In other words, an increased surface area of the tape side of the wafer assembly is in contact with the surface of the chuck table 330 for increased support.

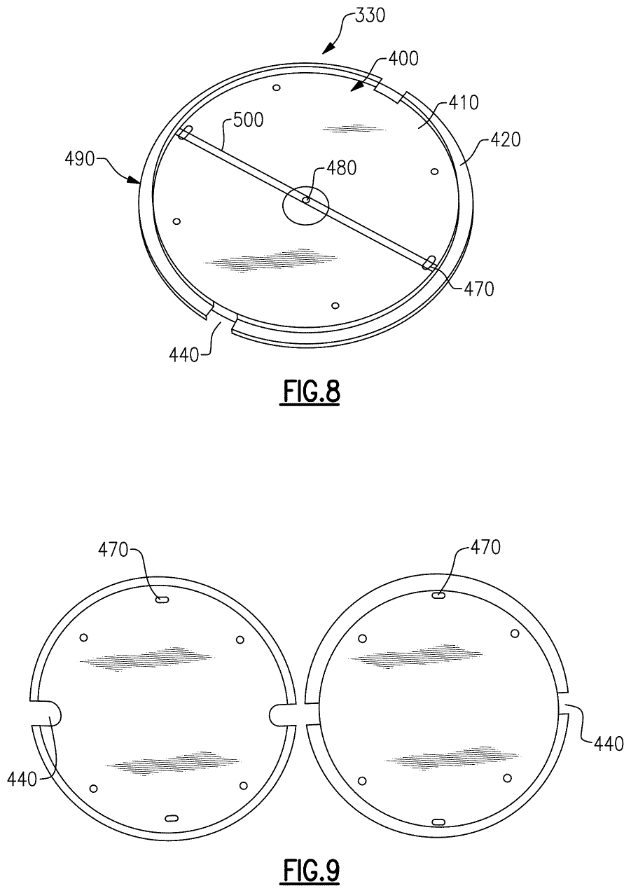

The differences between a chuck table according to aspects of the first embodiment discussed above (left hand side) and a chuck table according to aspects of the second embodiment discussed above (right hand side) are illustrated in FIG. 9. Attention is drawn to the configuration of the suction openings 470 and the handling indentations 440.

According to some aspects of the present disclosure, a chuck table is provided with further improved vacuum capability/functionality. As discussed above, a common problem with wafers of certain expansion distances is wafer damage/die cracking due to a suction force being applied to the edges of the wafer. In this second embodiment according to aspects of the present disclosure, the position of the suction openings is such that the vacuum pressure only has contact with a portion of the tape side of the wafer assembly directly opposing a portion of the wafer side on which the tape uncovered by the wafer. In other words, no suction force is applied on the actual wafer. Wafer damage or die cracking is, therefore, avoided. The above discussed advantages of the chuck table shown in FIG. 5 also apply to the chuck table shown in FIGS. 7 and 8.

Furthermore, as discussed above, another common problem with known chuck tables/the cleaning process is the wafers being thrown off the chuck table when high rotational speeds are reached during the cleaning cycle. The suction openings of the improved chuck table according to aspects of the present disclosure are configured to facilitate detecting, in real time, the presence of wafer-assembly tape on the chuck table. If it is detected that the wafer assembly is not positioned correctly on the chuck table, the cleaning process is interrupted. By then stopping the rotation of the chuck table, the wafer being thrown off the chuck table and subsequently damaged and rejected is avoided.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. A system for cleaning a wafer, the system comprising:
a vacuum source;
a chuck table configured to support a wafer assembly and to be in communication with both the vacuum source and the wafer assembly, such that in use a suction force is applied to the wafer assembly via the chuck table; and
a sensor component configured to detect the presence of the wafer assembly on the chuck table.

2. The system of claim 1 wherein the sensor component includes a pressure sensor configured to monitor the pressure associated with the suction force on the wafer assembly.

3. The system of claim 2 wherein the pressure sensor converts the measured pressure associated with the suction force on the wafer assembly into an electrical signal.

4. The system of claim 3 wherein the sensor component further includes a control component configured to determine whether the electrical signal from the pressure sensor is below a threshold value.

5. The system of claim 4 wherein the threshold value corresponds to a minimum signal that corresponds to the wafer assembly being correctly disposed on the chuck table.

6. The system of claim 5 wherein the control component is configured to issue an appropriate command to interrupt a cleaning cycle if it is determined that the electrical signal is below the threshold value.

7. The system of claim 5 wherein the control component is configured to issue an appropriate command to initiate a cleaning cycle if it is determined that the electrical signal is not below the threshold value.

8. The system of claim 5 wherein the control component is configured to issue an appropriate command to continue a cleaning cycle if it is determined that the electrical signal is not below the threshold value.

9. The system of claim 2 wherein the wafer assembly includes a wafer disposed on a portion of tape, the portion of tape having a first diameter that is larger than a second diameter of the wafer, and the wafer assembly being configured such that on a first face of the wafer assembly a peripheral area of the tape is uncovered by the wafer.

10. The system of claim 9 wherein the pressure sensor is configured to monitor the pressure associated with the suction force on a portion of a second face of the wafer assembly that directly opposes a portion of the peripheral area of the first face that is uncovered by the wafer.

11. A method for cleaning a wafer, the method comprising:
disposing a wafer assembly on a chuck table of a cleaning tool;
initiating a cleaning cycle;
applying a suction force to the wafer assembly via the chuck table; and
the cleaning tool monitoring the presence of the wafer assembly on the chuck table during the cleaning cycle.

12. The method of claim 11 wherein the presence of the wafer assembly on the chuck table is monitored by a sensor component of the cleaning tool.

13. The method of claim 12 wherein the sensor component includes a pressure sensor configured to monitor the pressure associated with the suction force on the wafer assembly.

14. The method of claim 13 wherein the pressure sensor converts the measured pressure associated with the suction force on the wafer assembly into an electrical signal.

15. The method of claim 14 wherein the sensor component further includes a control configured to determine whether the electrical signal from the pressure sensor is below a threshold value.

16. The method of claim 15 wherein the threshold value corresponds to a minimum signal that corresponds to the wafer assembly being correctly disposed on the chuck table.

17. The method of claim 16 wherein initiating the cleaning cycle triggers the control component to determine whether the electrical signal from the pressure sensor is below the threshold value.

18. The method of claim 17 wherein the control component issues an appropriate command to prevent the cleaning cycle from starting if it is determined that the electrical signal is below the threshold value.

19. The method of claim 17 wherein the control component issues an appropriate command to initiate the cleaning signal if it is determined that the electrical signal is not below the threshold value.

20. The method of claim 17 wherein the control component periodically determines whether the signal is below the threshold value throughout the cleaning cycle.
